(19) United States
(12) Patent Application Publication
(10) Pub. No.: US 2023/0097033 A1
(43) Pub. Date: Mar. 30, 2023

(54) SEMICONDUCTOR DEVICE HAVING AN OXIDE SEMICONDUCTING CHANNEL LAYER AND A METHOD OF MANUFACTURING THE SEMICONDUCTOR DEVICE

(71) Applicant: SK hynix Inc., Gyeonggi-do (KR)

(72) Inventor: Young Gwang YOON, Gyeonggi-do (KR)

(21) Appl. No.: 17/680,890

(22) Filed: Feb. 25, 2022

(30) Foreign Application Priority Data
Sep. 27, 2021 (KR) 10-2021-0126977

(51) Int. Cl. H01L 29/786; H01L 29/24; H01L 29/66

(52) U.S. Cl. CPC H01L 29/7869; H01L 29/78696; H01L 29/24; H01L 29/66969; H01L 29/66742

(57) ABSTRACT

A semiconductor device includes a substrate, a buried insulating layer on the substrate, a channel layer and a source/drain layer on the buried insulating layer, and a gate electrode pattern on the channel layer. The channel layer and the source/drain layer include an oxide semiconducting material. An oxygen vacancy concentration in the source/drain layer is higher than an oxygen vacancy concentration in the channel layer.

### CROSS-REFERENCE TO RELATED APPLICATIONS

The present application claims priority to Korean Patent Application No. 10-2021-0126977 filed on Sep. 27, 2021, which is herein incorporated by reference in its entirety.

### BACKGROUND

### 1. Field

The present disclosure relates to a semiconductor device having an oxide semiconducting channel layer and a method of manufacturing the semiconductor device.

### 2. Description of the Related Art

Many studies have been conducted to improve on/off characteristics of transistors.

### SUMMARY

Embodiments of the present disclosure provide a transistor having an oxide semiconducting channel layer and a semiconductor device including the transistor.

Embodiments of the present provide a method of manufacturing a transistor having an oxide semiconducting channel layer and a method of manufacturing a semiconductor device including the transistor.

According to an embodiment of the disclosure, a semiconductor device includes a substrate, a buried insulating layer on the substrate, a channel layer and a source/drain layer on the buried insulating layer, and a gate electrode pattern on the channel layer. The channel layer and the source/drain layer include an oxide semiconducting material. An oxygen vacancy concentration in the source/drain layer is higher than an oxygen vacancy concentration in the channel layer.

According to an embodiment of the disclosure, a semiconductor device includes a buried insulating layer on a substrate, a channel layer and a source/drain layer on the buried insulating layer, and a gate electrode pattern on the channel layer. The channel layer and the source/drain layer include an oxide semiconducting material. A hydrogen concentration in the source/drain layer is higher than a hydrogen concentration in the channel layer.

According to an embodiment of the disclosure, a semiconductor device includes a buried insulating layer on a substrate, a channel layer and a source/drain layer on the buried insulating layer, and a gate electrode pattern on the channel layer. The channel layer and the source/drain layer may include an oxide semiconducting material. An oxygen concentration in the channel layer may be higher than an oxygen concentration in the source/drain layer.

According to an embodiment of the disclosure, a method of manufacturing a semiconductor device includes forming a buried insulating layer on a substrate, forming a first oxide semiconducting layer on the buried insulating layer, forming a sacrificial gate pattern on the first oxide semiconducting layer, forming gate spacers on both sides of the sacrificial gate pattern, forming a gate groove by removing the sacrificial gate pattern between the gate spacers, exposing sides of the buried insulating layer and the first oxide semiconducting layer by removing a portion of the first oxide semiconducting layer exposed in the gate groove, forming a source/drain layer by implanting hydrogen ions into the first oxide semiconducting layer, forming a second oxide semiconducting layer on the buried insulating layer exposed in the gate groove, forming a channel layer by implanting oxygen ions into the second oxide semiconducting layer, and forming a gate electrode pattern in the gate groove.

According to an embodiment of the disclosure, a method of manufacturing a semiconductor device includes forming a semiconductor device, the method may include forming a buried insulating layer on a substrate, forming a first oxide semiconducting layer on the buried insulating layer, forming an interlayer insulating layer on the first oxide semiconducting layer, forming a groove passing through the interlayer insulating layer and the first oxide semiconducting layer to expose a top surface of the buried insulating layer, forming a second oxide semiconducting layer in the groove, forming a gate electrode pattern in the groove, and implanting oxygen ions into the second oxide semiconducting layer.

These and other features of the present invention will become understood by the those with ordinary skill in the art to which the present invention belongs from the following drawings and detailed description.

### BRIEF DESCRIPTION OF THE DRAWINGS

FIGS. 1A to 1I are schematic longitudinal cross-sectional views of semiconductor devices according to embodiments of the present disclosure.

FIGS. 2A to 2M are longitudinal cross-sectional views illustrating a method of manufacturing a semiconductor device according to an embodiment of the present disclosure.

FIG. 3 is a longitudinal cross-sectional view illustrating a method of manufacturing a semiconductor device according to an embodiment of the present disclosure.

FIG. 4 is a longitudinal cross-sectional view illustrating a method of manufacturing a semiconductor device according to an embodiment of the present disclosure.

FIGS. 5A and 5B are longitudinal cross-sectional views illustrating methods of manufacturing a semiconductor device according to embodiments of the present disclosure.

FIGS. 6A and 6B are longitudinal cross-sectional views illustrating methods of manufacturing semiconductor devices according to embodiments of the present disclosure.

### DETAILED DESCRIPTION

Various embodiments of the present disclosure will be described below in more detail with reference to the accompanying drawings. The present disclosure may, however, be embodied in different forms and should not be construed as limited to the embodiments set forth herein. Rather, these embodiments are provided to make this disclosure thorough and complete, and fully convey the scope of the present disclosure to those skilled in the art. The spirit and scope of the disclosure are as defined in the claims.

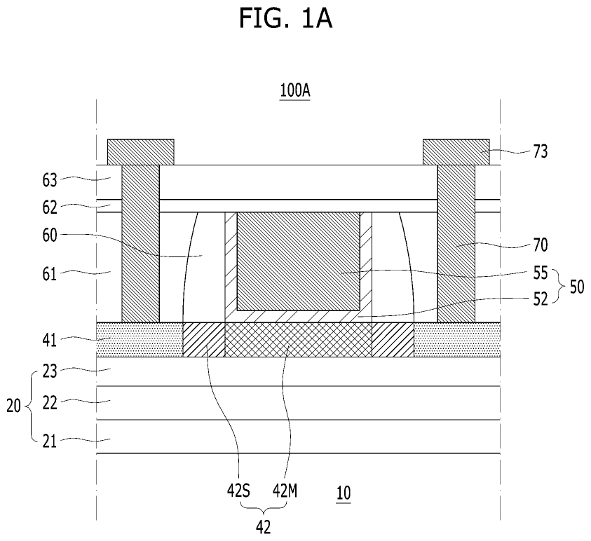

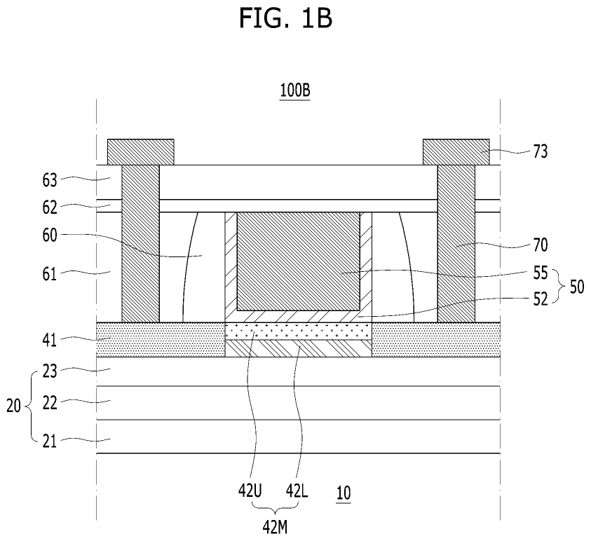

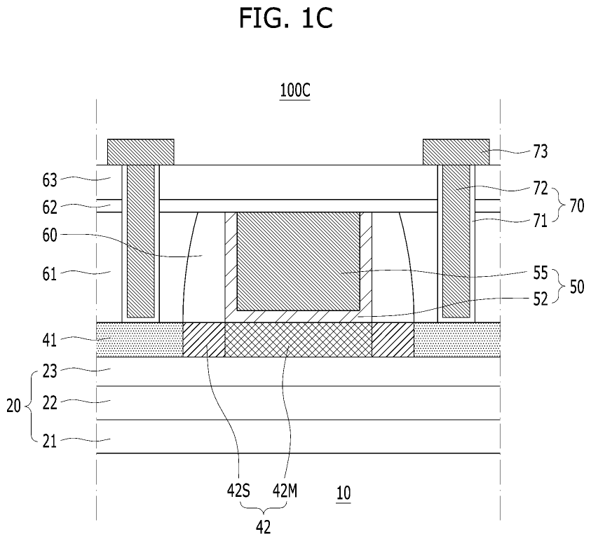

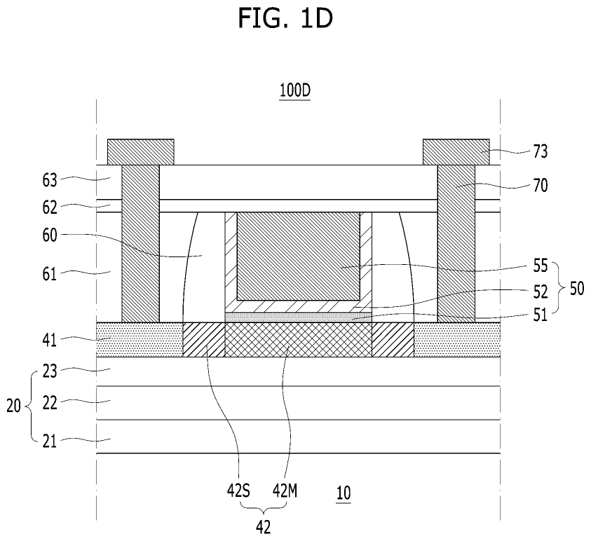

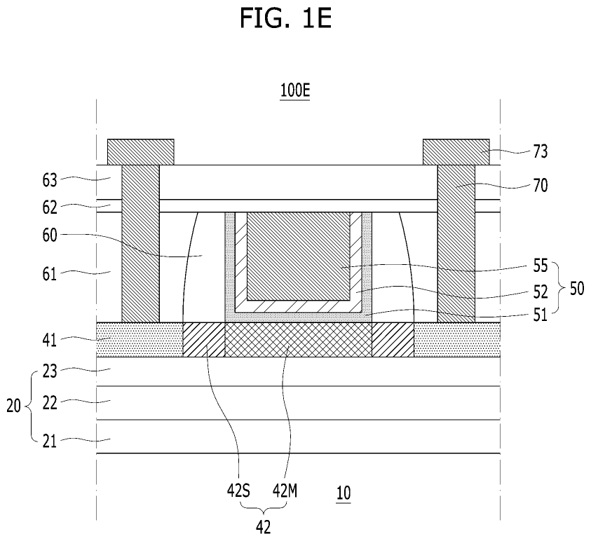

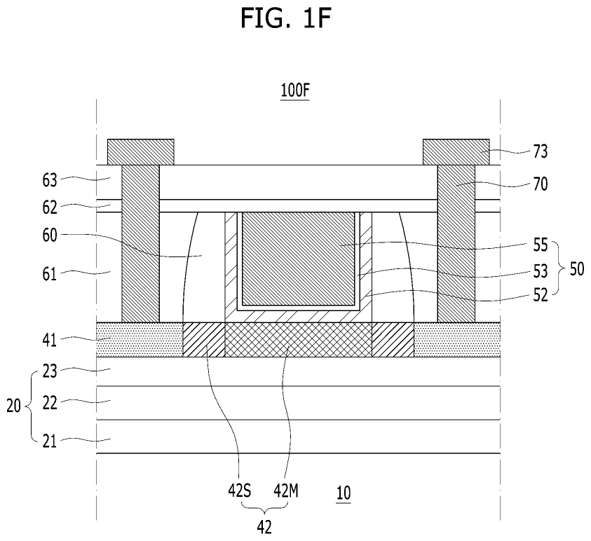

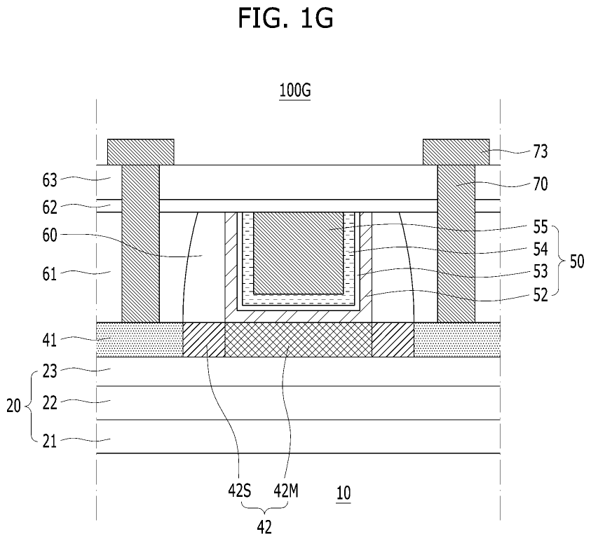

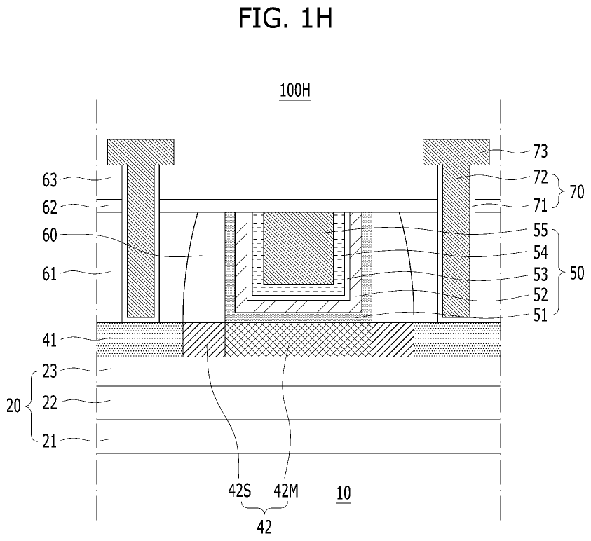

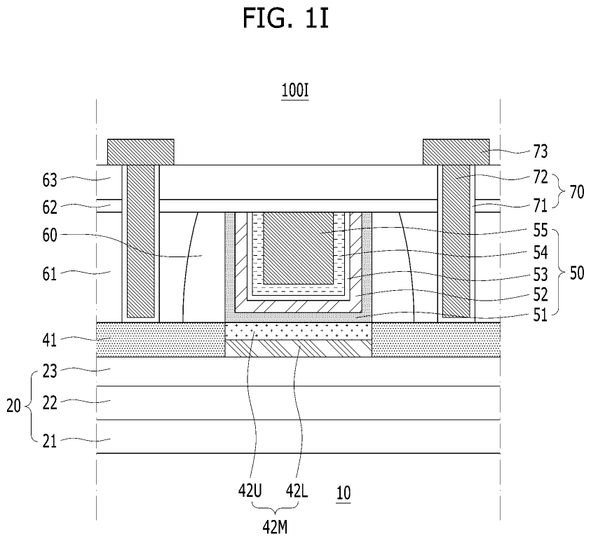

FIGS. 1A to 1I are schematic longitudinal cross-sectional views of semiconductor devices 100A-100I according to embodiments of the present disclosure. Referring to FIG. 1A, a semiconductor device 100A according to an embodiment of the present disclosure may include a substrate 10, a buried insulating layer 20 stacked on the substrate 10, a source/drain layer 41 and a channel layer 42, a gate electrode pattern 50 and gate spacers 60, the interlayer insulating layers 61, 62, and 63, a contact pattern 70, and a conductive pattern 73 on the buried insulating layer 20.

The substrate 10 may include a semiconductor layer such as a silicon wafer. In some embodiments, the substrate 10 may include one of a compound semiconductor layer, an epitaxially grown silicon layer, silicon-on-insulator (SOI), or other various layers of semiconducting material.

The buried insulating layer 20 may include a lower buried insulating layer 21, a middle buried insulating layer 22, and an upper buried insulating layer 23. The lower buried insulating layer 21 may include an insulating material having good adhesion to the substrate 10. For example, the lower buried insulating layer 21 may include a silicon oxide (SiO₂) layer. The middle buried insulating layer 22 may have good reactivity with hydrogen. For example, the middle buried insulating layer 22 may include a silicon oxy-carbide (SiOC) layer. The upper buried insulating layer 23 may include a silicon nitride (SiN) based insulating material later to have an excellent etch selectivity to the source/drain layer 41 and the channel layer 42. The lower buried insulating layer 21 and the upper buried insulating layer 23 may have lower hydrogen reactivity than the middle buried insulating layer 22. Accordingly, the middle buried insulating layer 22 may trap hydrogen ions, and the lower buried insulating layer 21 and the upper buried insulating layer 23 may block the diffusion of hydrogen ions. That is, the hydrogen ions may combine with dangling bonds in the buried insulating layer 20.

The source/drain layer 41 and the channel layer 42 may include an oxide semiconducting material. The source/drain layer 41 and the channel layer 42 may include indium (In) to improve carrier mobility. The source/drain layer 41 and the channel layer 42 may include gallium (Ga) and zinc (Zn) for chemical stability. For example, the source/drain layer 41 and the channel layer 42 may include at least one of InGaZnO, InGaZnSnO, InSnO, InSnZnO, SiInGaZnO, SiInGaZnSnO, SiInSnO, SiInSnZnO, AlGaZnO, AlGaZnSnO, AlSnO, AlSnZnO, SiAlGaZnO, SiAlGaZnSnO, SiAlSnO, SiAlSnZnO, InGaMgO, InGaMgSnO, InSnMgO, SiInGaMgO, SiInGaMgSnO, SiInSnMgO, AlGaMgO, AlGaMgSnO, AlSnMgO, SiAlGaMgO, SiAlGaMgSnO, SiAlSnMgO, or other oxide materials.

The channel layer 42 may include a main channel layer 42M and a side channel layer 42S. The main channel layer 42M may vertically overlap with the gate electrode pattern 50. The side channel layer 42S may vertically overlap with the gate spacers 60. The source/drain layer 41 may be positioned outside or spaced apart from the gate electrode pattern 50 and the gate spacers 60 to be in contact with the contact pattern 70. The source/drain layer 41 and the channel layer 42 may be positioned at the same level. The source/drain layer 41 and the channel layer 42 may be horizontally aligned. The source/drain layer 41 and the channel layer 42 may have the same thickness measured in the stacking direction.

The hydrogen concentration in the source/drain layer 41 may be higher than the hydrogen concentration in the channel layer 42. In an embodiment, the hydrogen concentration in the source/drain layer 41 may be higher than the hydrogen concentration in the main channel layer 42M and similar to the hydrogen concentration in the side channel layer 42S. The hydrogen concentration in the side channel layer 42S may be higher than the hydrogen concentration in the main channel layer 42M. The oxygen vacancy concentration in the source/drain layer 41 may be higher than the oxygen vacancy concentration in the channel layer 42. In an embodiment, the oxygen vacancy concentration in the source/drain layer 41 may be higher than the oxygen vacancy concentration in the main channel layer 42M and the oxygen vacancy concentration in the side channel layer 42S.

The oxygen concentration in the channel layer 42 may be higher than the oxygen concentration in the source/drain layer 41. For example, the oxygen concentration in the side channel layer 42S may be higher than the oxygen concentration in the source/drain layer 41, and the oxygen concentration in the main channel layer 42M may be higher than the oxygen concentration in the side channel layer 42S.

The gate electrode pattern 50 may include a gate insulating layer 52 and a gate electrode 55. The gate insulating layer 52 may surround side surfaces and a lower surface of the gate electrode 55 in a U-shape. The gate insulating layer 52 may include at least one of first compounds containing hafnium (Hf), such as hafnium oxide (HfO), hafnium nitride (HfN), hafnium oxy-nitride (HfON), hafnium silicon nitride (HfSiN), hafnium aluminum oxide (HfAlO), or hafnium aluminum nitride (HfAlN), or second compounds containing bismuth (Bi), barium (Ba), zinc (Zn), lead (Pb), or strontium (Sr). The gate electrode 55 may include at least one of a polycrystalline silicon layer, a silicide layer, a metal layer, a metal alloy layer, and a metal compound layer.

The gate spacers 60 may be formed on both side surfaces of the gate electrode pattern 50. The gate spacers 60 may be formed of any suitable material including, for example, silicon nitride (SiN).

The interlayer insulating layers 61, 62, and 63 may include a lower interlayer insulating layer 61, a middle interlayer insulating layer 62, and an upper interlayer insulating layer 63. The lower interlayer insulating layer 61 may include a silicon oxide based insulating material such as silicon oxide (SiO₂), silicon hydro-oxide (SiHO), silicon oxy-carbide (SiOC), or silicon hydro-oxy-carbide (SiHOC). The lower interlayer insulating layer 61 may be formed on the source/drain layer 41 to surround the gate spacers 60 which surround the side surfaces of the gate electrode pattern 50. Upper surfaces of the lower interlayer insulating layer 61, the gate spacers 60, and the gate electrode pattern 50 may be coplanar. The middle interlayer insulating layer 62 may include an insulating material denser and harder than the lower interlayer insulating layer 61. For example, the middle interlayer insulating layer 62 may include at least one of a silicon nitride (SiN) layer, a silicon oxy-nitride (SiON) layer, a silicon carbon nitride (SiCN) layer, a silicon boron nitride (SiBN) layer, a silicon boron carbon nitride (SiBCN) layer, and other nitride based insulating layers. The upper interlayer insulating layer 63 may include a silicon oxide based insulating material such as SiO₂, SiHO, SiOC, or SiHOC.

The contact pattern 70 may vertically penetrate the interlayer insulating layers 61, 62, and 63 to be in contact with the source/drain layer 41 at one end thereof and with the conductive pattern 73 at an opposite end thereof. The contact pattern 70 may have a pillar shape. The contact pattern 70 may include any suitable conductor such as a metal.

The conductive pattern 73 may be disposed on the upper interlayer insulating layer 63 and the contact pattern 70. The conductive pattern 73 may include a line-type interconnection pattern extending horizontally or a post-type or cylinder type capacitor electrode pattern extending vertically. The conductive pattern 73 may include at least one of a polycrystalline silicon pattern, a silicide pattern, a metal pattern, a metal alloy pattern, and a metal compound pattern.

In the semiconductor device 100A according to an embodiment of the present disclosure, hydrogen ions in the source/drain layer 41 may disrupt oxygen bonding of the oxide semiconducting material. That is, hydrogen ions in the oxide semiconducting material of the source/drain layer 41 can increase oxygen vacancies in the source/drain layer 41. The oxygen vacancies can increase carrier concentration or carrier mobility. Accordingly, the electrical resistance of the source/drain layer 41 can decrease and its conductivity increase.

The oxygen ions in the channel layer 42 can reduce the oxygen vacancies by replenishing oxygen bonds in the oxide semiconducting material of the channel layer 42. As described above, when the oxygen vacancies are reduced, the carrier concentration and the carrier mobility can be also reduced. Accordingly, an off-current (leakage current) of the transistor can be reduced and data retention can be improved.

Referring to FIG. 1B, a semiconductor device 100B according to an embodiment of the present disclosure may include a main channel layer 42M having a lower channel layer 42L and an upper channel layer 42U as compared to the semiconductor device 100A shown in FIG. 1A. The side channel layer 42S of FIG. 1A may be omitted. An oxygen concentration in the lower channel layer 42L may be higher than an oxygen concentration in the upper channel layer 42U. Accordingly, the carrier concentration or carrier mobility in the lower channel layer 42L may be lower than the carrier concentration or carrier mobility in the upper channel layer 42U. The on-off of the upper channel layer 42U can be appropriately controlled by the voltage of the gate electrode pattern 50. The off-current of the upper channel layer 42U can be smaller than the off-current of the lower channel layer 42L. That is, the carrier concentration or the carrier mobility in the upper channel layer 42U may be greater than the carrier concentration or the carrier mobility in the lower channel layer 42L. The oxygen vacancy concentration or hydrogen concentration in the source/drain layer 41 may be greater than the oxygen vacancy concentration or hydrogen concentrations of the lower channel layer 42L and the upper channel layer 42U.

Referring to FIG. 1C, a semiconductor device 100C according to an embodiment of the present disclosure may include a contact barrier layer 71 and a contact pattern having a contact core 72 as compared to the semiconductor device 100A described with reference to FIG. 1A. The contact barrier layer 71 may surround side surfaces and a lower surface of the contact core 72. The contact barrier layer 71 may include at least one of titanium (Ti), titanium nitride (TiN), tantalum (Ta), tantalum nitride (TaN), tungsten nitride (WN), titanium aluminum nitride (TiAlN), tantalum aluminum nitride (TaAlN), and other suitable barrier metals. The contact core 72 may include a suitable metal such as, for example, tungsten (W).

Referring to FIGS. 1D and 1E, semiconductor devices 100D and 100E according to embodiments of the present disclosure may include a gate electrode pattern 50 further including an interface insulating layer 51 as compared to the semiconductor device 100A described with reference to FIG. 1A. Referring to FIG. 1D, the interface insulating layer 51 may have a plate shape positioned between the lower surface of the gate insulating layer 52 and a main channel layer 42M. Referring to FIG. 1E, the interface insulating layer 51 may surround the side surfaces and the lower surface of the gate insulating layer 52 in a U-shape. The interface insulating layer 51 may include a silicon oxide (SiO₂) layer or an aluminum oxide (Al₂O₃) layer.

Referring to FIG. 1F, a semiconductor device 100F according to an embodiment of the present disclosure may include a gate electrode pattern 50 having a gate barrier layer 53 as compared to the semiconductor device 100A described with reference to FIG. 1A. The gate barrier layer 53 may surround side surfaces and the lower surface of the gate electrode 55 in a U-shape. The gate barrier layer 53 may be positioned between the gate electrode 55 and the gate insulating layer 52. The gate barrier layer 53 may include at least one of Ti, TiN, Ta, TaN, WN, TiAlN, TaAlN, and other suitable barrier metals. The channel layer 42 may include the main channel layer 42M and the side channel layer 42S as in FIG. 1A.

Referring to FIG. 1G, a semiconductor device 100G according to an embodiment of the present disclosure may include a gate electrode pattern 50 having a gate barrier layer 53 and a work function adjustment layer 54. The work function adjustment layer 54 may be disposed between the gate barrier layer 53 and the gate electrode 55. The work function adjustment layer 54 may surround side surfaces and the lower surface of the gate electrode 55 in a U-shape. The work function adjustment layer 54 may include at least one of AlN, TiAlN, TiAlC, TiAlCN, TiAl, and other metal nitrides including Al. The gate barrier layer 53 may surround side surfaces and the lower surface of the work function adjustment layer 54 in a U-shape.

Referring to FIG. 1H, a semiconductor device 100H according to an embodiment of the present disclosure may include a different gate electrode pattern 50 and a contact pattern 70 as compared with the semiconductor devices 100A-100G described with reference to FIGS. 1A to 1G. The gate contact pattern 50 may include an interface insulating layer 51, a gate insulating layer 52, a gate barrier layer 53, a work function adjustment layer 54, and a gate electrode 55. The contact pattern 70 may include a contact barrier layer 71 and a contact core 72.

Referring to FIG. 1I, a semiconductor device 100I according to an embodiment of the present disclosure may include a main channel layer 42M having a lower channel layer 42L and an upper channel layer 42U as compared to the semiconductor device 100H described with reference to FIG. 1H.

Reference numerals not described in FIGS. 1B to 1I can be understood by referring to other drawings.

The semiconductor devices 100A-100I according to the embodiments of the present disclosure described with reference to FIGS. 1A to 1I may include the source/drain layer 41 having a higher oxygen vacancy concentration or higher hydrogen concentration, and a channel layer 42 having a lower oxygen vacancy concentration or a lower hydrogen concentration. The oxygen concentration in the channel layer 42 may be higher than the oxygen concentration in the source/drain layer 41. Accordingly, the off-current of the channel layer 42 can be reduced and the carrier mobility of the source/drain layer 41 can be improved.

Features of the semiconductor devices 100A-100I according to the embodiments of the disclosure described with reference to FIGS. 1A to 1I can be variously combined.

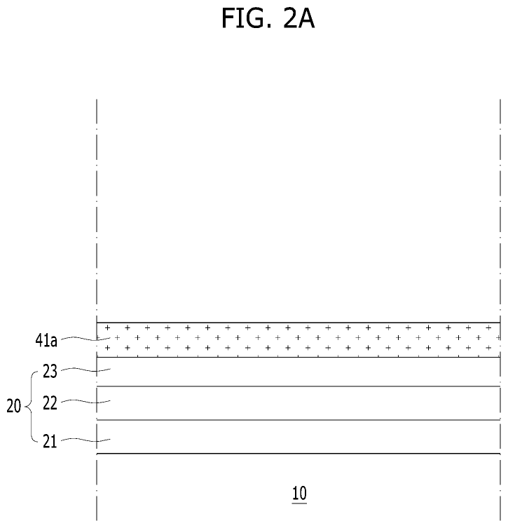

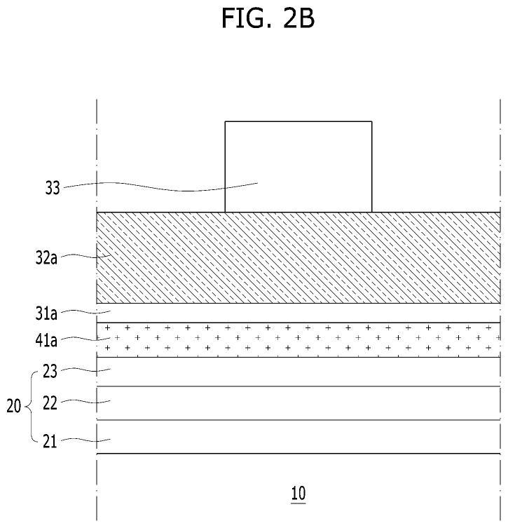

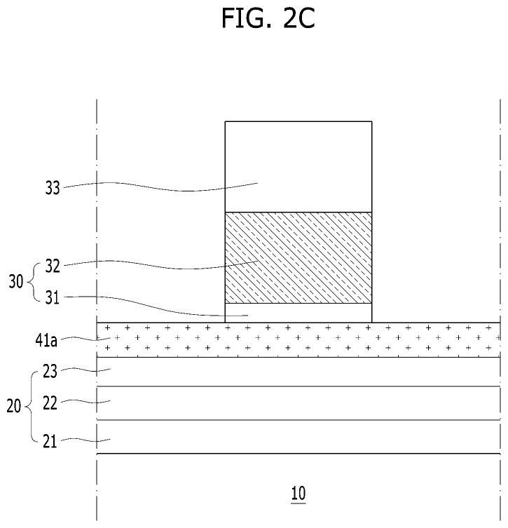

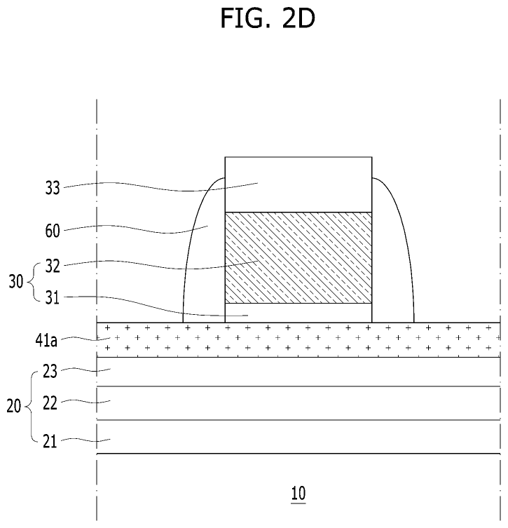

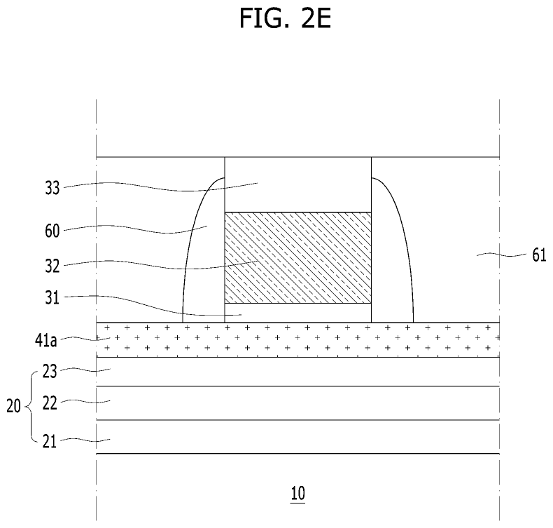

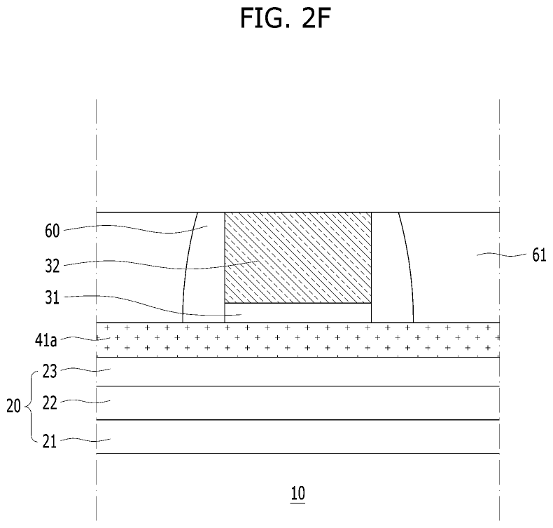

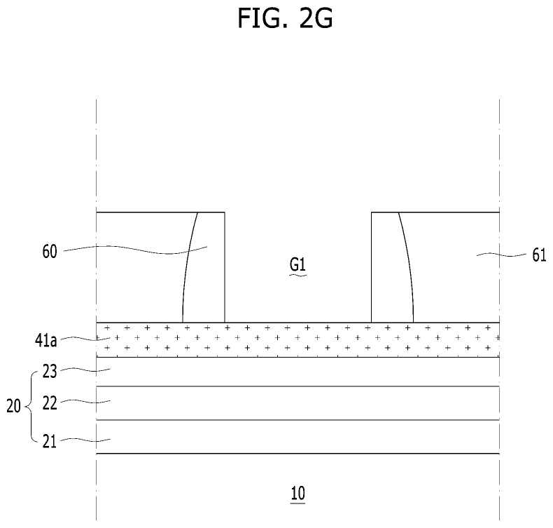

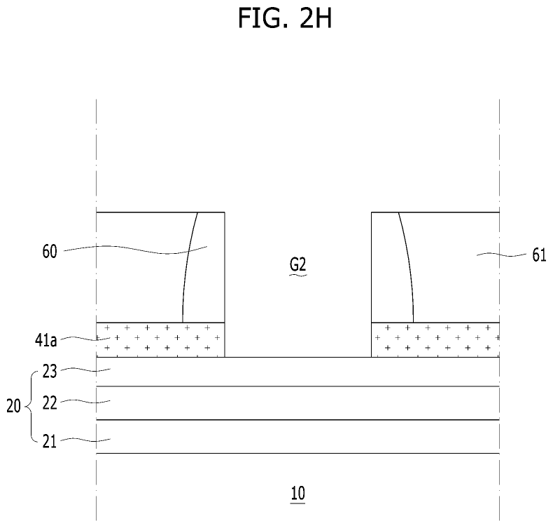

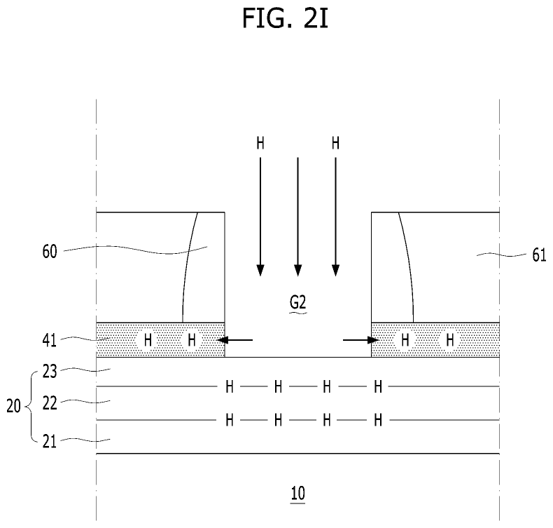

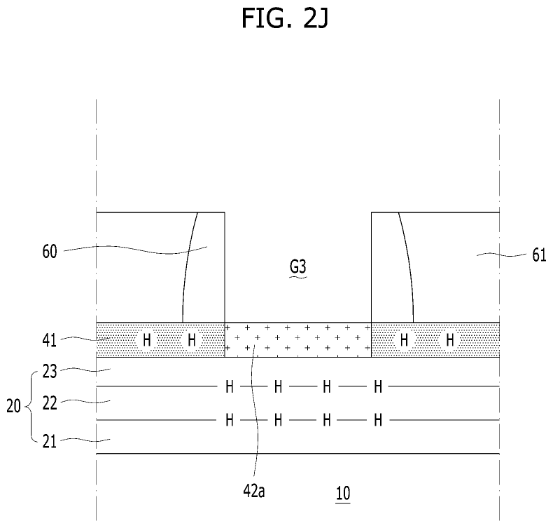

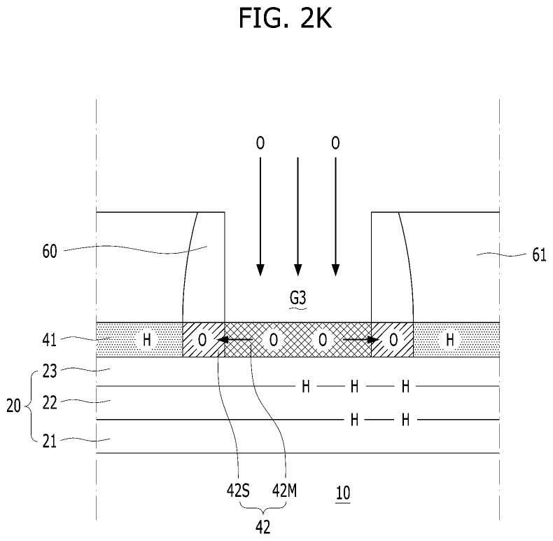

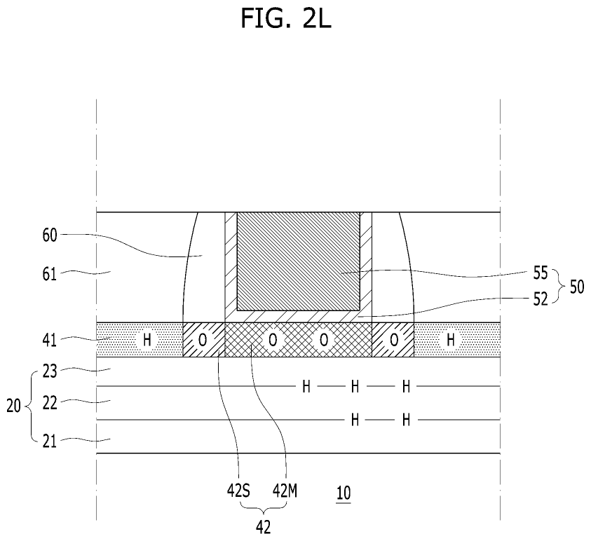

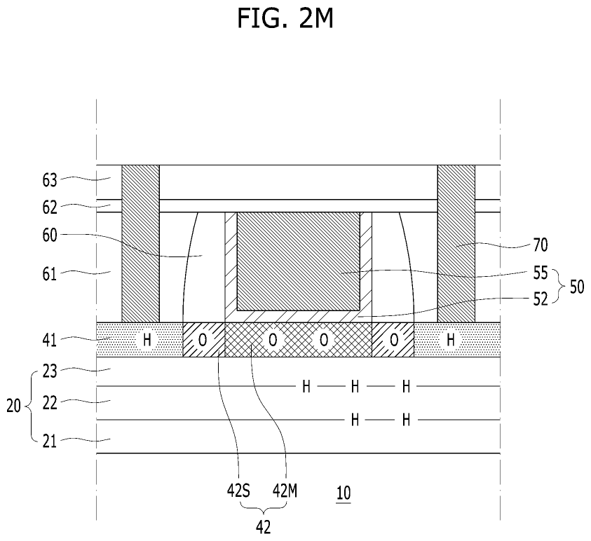

FIGS. 2A to 2M are longitudinal cross-sectional views illustrating a method of manufacturing a semiconductor device according to an embodiment of the present disclosure. Referring to FIG. 2A, a method of manufacturing a semiconductor device according to an embodiment of the present disclosure may include performing a deposition process to form a buried insulating layer 20 on a substrate 10 and forming a first oxide semiconducting layer 41a on the buried insulating layer 20. The buried insulating layer 20 may include a lower buried insulating layer 21, a middle buried insulating layer 22, and an upper buried insulating layer 23. Forming the lower buried insulating layer 21 may include performing an oxidation process or a deposition process to form a silicon oxide (SiO₂) layer on the substrate 10. Forming the middle buried insulating layer 22 may include performing a deposition process to form a silicon carbide oxide (SiCO) layer. Forming the upper buried insulating layer 23 may include performing a nitride deposition process to form a silicon nitride (SiN) layer. Forming the first oxide semiconducting layer 41a may include performing a deposition process to form an oxide-based semiconducting material layer on the buried insulating layer 20.

Referring to FIG. 2B, the method may further include forming a sacrificial insulating layer 31a, a sacrificial gate electrode layer 32b, and a mask pattern 33 on the first oxide semiconducting layer 41a. Forming the sacrificial insulating layer 31a may include performing a deposition process to form a silicon oxide (SiO₂) layer. Forming the sacrificial gate electrode layer 32b may include performing a deposition process to form a polycrystalline silicon layer. Forming the mask pattern 33 may include performing a coating process and a photolithography process to form a photoresist pattern or performing a deposition process and a selective etching process to form a hard mask pattern. For example, the mask pattern 33 may include an organic polymeric material or silicon nitride (SiN).

Referring to FIG. 2C, the method may further include etching the sacrificial gate electrode layer 32b and the sacrificial insulating layer 31a to form a sacrificial gate pattern 30. The sacrificial gate pattern 30 may include a sacrificial insulating pattern 31 and a sacrificial gate electrode pattern 32. Forming the sacrificial gate pattern 30 may include performing an etching process using the mask pattern 33 as an etching mask.

Referring to FIG. 2D, the method may further include forming gate spacers 60 on both side surfaces of the sacrificial gate pattern 30. Forming the gate spacers 60 may include entirely forming a silicon nitride (SiN) layer and performing an etch-back process. A vertical thickness of the mask pattern 33 may be reduced.

Referring to FIG. 2E, the method may further include forming a lower interlayer insulating layer 61 and performing a first planarization process such as a CMP (chemical mechanical polishing) process. Forming the lower interlayer insulating layer 61 may include performing a deposition process to form a silicon oxide-based insulating material such as SiO₂, SiOH, SiOC, or SiHOC. The mask pattern 33 may be used as a polishing stopper or a polishing resistive layer in the first planarization process.

Referring to FIG. 2F, the method may further include performing a second planarization process such as the CMP to expose an upper surface of the sacrificial gate electrode pattern 32 by removing the mask pattern 33. After the second planarization process, the upper surfaces of the lower interlayer insulating layer 61, the gate spacers 60, and the sacrificial gate electrode pattern 32 may become coplanar.

Referring to FIG. 2G, the method may further include removing the sacrificial gate pattern 30 to form a first gate groove G1. An upper surface of the first oxide semiconducting layer 41a may be exposed in the first gate groove G1.

Referring to FIG. 2H, the method may further include removing the first oxide semiconducting layer 41a exposed in the first gate groove G1 to form a second groove G2 that exposes an upper surface of the upper buried insulating layer 23. Side surfaces of the first oxide semiconducting layer 41a may be also exposed in the second gate groove G2. The second gate groove G2 may be defined by the gate spacers 60, the exposed side surfaces of the first oxide semiconducting layer 41a, and the exposed upper surface of the upper buried insulating layer 23.

Referring to FIG. 2I, the method may further include performing a hydrogen implantation process to implant hydrogens H (e.g., hydrogen ions (H+) or hydrogen radicals (H*)) into the first oxide semiconducting layer 41a and the buried insulating layer 20 exposed in the second gate groove G2. The hydrogen implantation process may include performing a hydrogen plasma process or an annealing process in a hydrogen atmosphere. The hydrogen ions implanted in the first oxide semiconducting layer 41a may disrupt oxygen bonds in the first oxide semiconducting layer 41a to increase oxygen vacancies and an oxygen concentration. The first oxide semiconducting layer 41a may be changed into a source/drain layer 41 by implanting hydrogen ions. The hydrogen ions may be also implanted into the buried insulating layer 20. The hydrogen ions implanted in the buried insulating layer 20 may be mainly trapped at interfaces of the buried insulating layer 20 having especially many dangling bonds. The upper buried insulating layer 23 and the lower buried insulating layer 21 may retard penetration and movement of hydrogen ions.

Referring to FIG. 2J, the method may further include forming a second oxide semiconducting layer 42a on the upper buried insulating layer 23 in the second gate groove G2. The second oxide semiconducting layer 42a may include one of various oxide semiconducting materials such as the first oxide semiconducting layer 41a. For example, the first oxide semiconducting layer 41a and the second oxide semiconducting layer 42a may include the same material. The second gate groove G2 may be changed into a third gate groove G3 defined by the gate spacers 60 and the second oxide semiconducting layer 42a.

Referring to FIG. 2K, the method may further include performing the oxygen implantation process to implant oxygens O (oxygen ions (O—) or oxygen radicals (O*)) into the second oxide semiconducting layer 42a. The oxygen implantation process may include performing an oxygen plasma process or an annealing process in an oxygen atmosphere. The oxygen ions implanted into the second oxide semiconducting layer 42a may diffuse into the source/drain layer 41 to form a side channel layer 42S. The second oxide semiconducting layer 42a exposed in the third gate groove G3 may form the main channel layer 42M. The implanted oxygen ions can replenish oxygen bonds to reduce oxygen vacancies.

Referring to FIG. 2L, the method may further include performing a gate forming process to form a gate electrode pattern 50. The gate forming process may include forming a gate insulating layer 52 and a gate electrode 55 on the main channel layer 42M exposed in the third gate groove G3. Forming the gate insulating layer 52 may include performing a deposition process to conformally form an insulating layer having a high dielectric constant on the side surfaces and the lower surface of the third gate groove G3. The gate insulating layer 52 may have a shape, for example a U-shape, surrounding the side surfaces and the lower surface of the gate electrode 55. Forming the gate electrode 55 may include performing a deposition process or a plating process to fill an inside of the third gate groove G3 with a conductor such as a metal. The method may further include performing a third planarization process such as the CMP to form coplanar upper surfaces of the lower interlayer insulating layer 61, the gate spacers 60, and the gate electrode pattern 50.

Referring to FIG. 2M, the method may further include forming a middle interlayer insulation layer 62 on upper surfaces of the lower interlayer insulation layer 61, the gate spacers 60, and the gate electrode pattern 50, forming an upper interlayer insulating layer 63 on the middle interlayer insulating layer 62, forming a contact hole vertically penetrating the upper interlayer insulating layer 63, the middle interlayer insulating layer 62, and the lower interlayer insulating layer 61 to expose upper surfaces of the source/drain layers 41, and filling the contact hole with a conductor to form a contact pattern 70. Forming the middle interlayer insulating layer 62 may include performing a deposition process to form a nitride-based insulating material layer. Forming the upper interlayer insulating layer 63 may include performing a deposition process to form an oxide-based insulating layer. Forming the contact hole may include performing a photolithography process to penetrate the upper interlayer insulating layer 63, the middle interlayer insulating layer 62, and the lower interlayer insulating layer 61 to partially expose the upper surface of the source/drain layer 41. Forming the contact pattern 70 may include performing a deposition process or a plating process to fill an inside of the contact hole with a conductor such as a metal.

Thereafter, further referring to FIG. 1A, the method may further include forming a conductive pattern 73 on the contact pattern 70. Forming the conductive pattern 73 may include performing a deposition process and a patterning process to form at least one of a polycrystalline silicon pattern, a silicide pattern, a metal pattern, a metal alloy pattern, and a metal compound pattern having a line shape or a pillar shape.

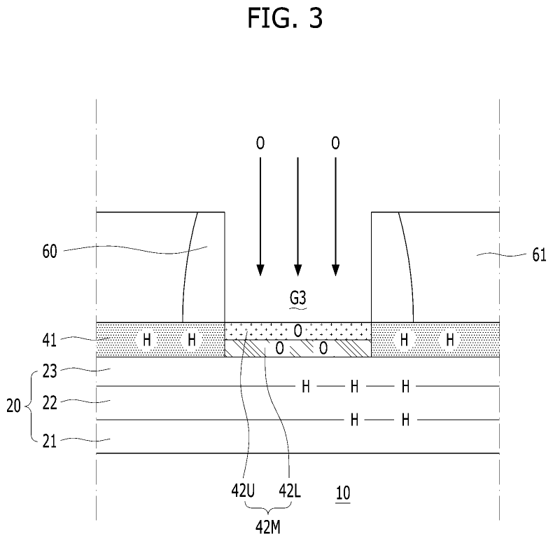

FIG. 3 is a longitudinal cross-sectional view illustrating a method of manufacturing a semiconductor device according to an embodiment of the present disclosure. Referring to FIG. 3, the method of manufacturing a semiconductor device according to an embodiment of the present invention may include performing the processes described with reference to FIGS. 2A to 2J and performing an oxygen implantation process to implant oxygen ions into the second oxide semiconducting layer 42a. The oxygen ions may be mainly implanted into a lower region of the second oxide semiconducting layer 42a. That is, the lower region of the second oxide semiconducting layer 42a may be formed as a lower channel layer 42L including a high oxygen concentration, and un upper region of the second oxide semiconducting layer 42a may be formed as an upper channel layer 42U including a lower oxygen concentration. The main channel layer 42M may include a lower channel layer 42L including oxygen ions implanted at a relatively higher concentration and an upper channel layer 42U including oxygen ions implanted at a relatively lower concentration. The side channel layer 42S of FIG. 2J may be omitted.

Thereafter, the method may further include performing the processes described with reference to FIGS. 2L and 2M, and forming a conductive pattern 73 on the contact pattern 70. The semiconductor device 100B shown in FIG. 1B may be manufactured by the above process.

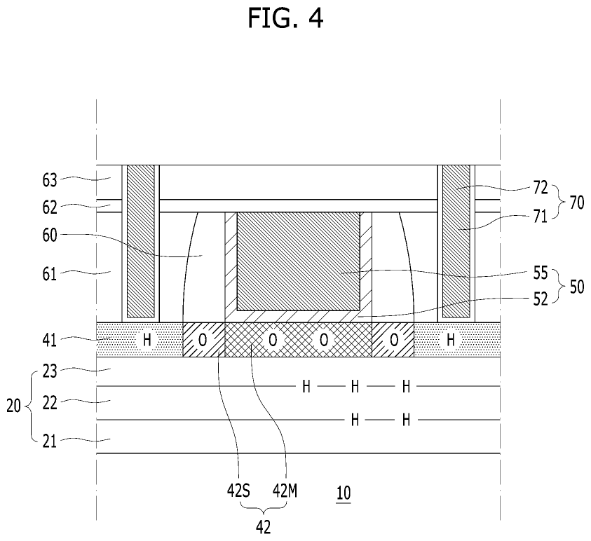

FIG. 4 is a longitudinal cross-sectional view illustrating a method of manufacturing a semiconductor device according to an embodiment of the present disclosure. Referring to FIG. 4, a method of manufacturing a semiconductor device according to an embodiment of the present disclosure may include performing the processes described with reference to FIGS. 2A to 2L, forming a middle interlayer insulating layer 62 on upper surfaces of a lower interlayer insulating layer 61, gate spacers 60, and a gate electrode pattern 50, forming an upper interlayer insulating layer 63 on the middle interlayer insulating layer 62, forming a contact hole vertically penetrating the upper interlayer insulating layer 63, the middle interlayer insulating layer 62, and the lower interlayer insulating layer 61 to expose upper surfaces of the source/drain layers 41, and filling the contact hole with a conductor to form a contact pattern 70. The contact pattern 70 may include a contact barrier layer 71 conformally formed on side surfaces of the contact hole and a contact core 72 filling an inside of the contact hole. The contact barrier layer 71 may be also formed on the surface of the source/drain layer 41 exposed in the contact hole. Forming the contact barrier layer 71 may include performing a deposition process to conformally form a barrier metal layer on sidewalls and bottom surfaces of the contact hole. Forming the contact core 72 may include performing a deposition process or a plating process to fill an inside of the contact hole with a conductor such as a metal. Thereafter, referring to FIG. 1C, the method may further include forming the conductive pattern 73 on the contact pattern 70 to manufacture the semiconductor device 100C.

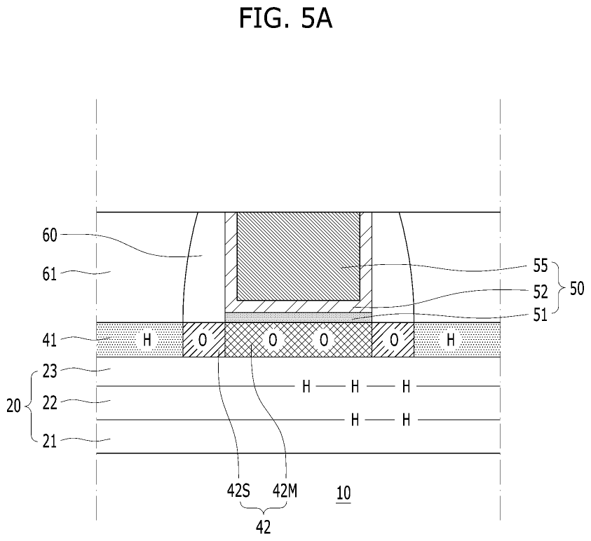

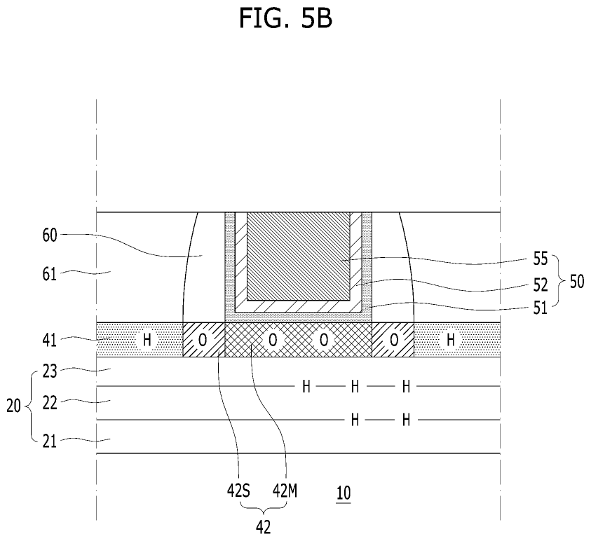

FIGS. 5A and 5B are longitudinal cross-sectional views illustrating methods of manufacturing a semiconductor device according to embodiments of the present disclosure. Referring to FIGS. 5A and 5B, methods of manufacturing semiconductor devices according to embodiments of the present disclosure may include performing the processes described with reference to FIGS. 2A to 2K, and performing a gate forming process to form a gate electrode pattern 50. The gate forming process may include forming the interface insulating layer 51, the gate insulating layer 52, and the gate electrode 55 on the main channel layer 42M exposed in the third gate groove G3. Forming the interface insulating layer 51 may include performing a deposition process to form a silicon oxide (SiO₂) layer or aluminum oxide (Al₂O₃) layer on the main channel layer 42M. Referring to FIG. 5A, the interface insulating layer 51 may have a plate shape.

Referring to FIG. 5B, the interface insulating layer 51 may have a U-shape surrounding side surfaces and the lower surface of the gate insulating layer 52. Thereafter, the method may further include performing the processes described with reference to FIG. 2M and forming the conductive pattern 73 on the contact pattern 70 with further reference to FIG. 1D or 1E. The semiconductor devices 100D and 100E shown in FIGS. 1D and 1E may be manufactured by the above described processes.

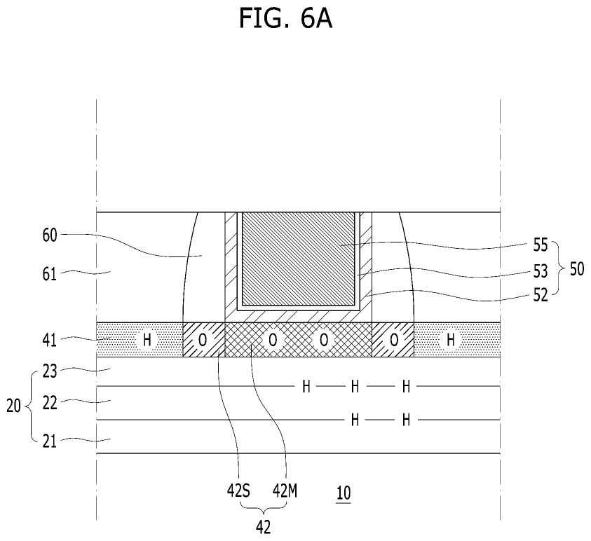

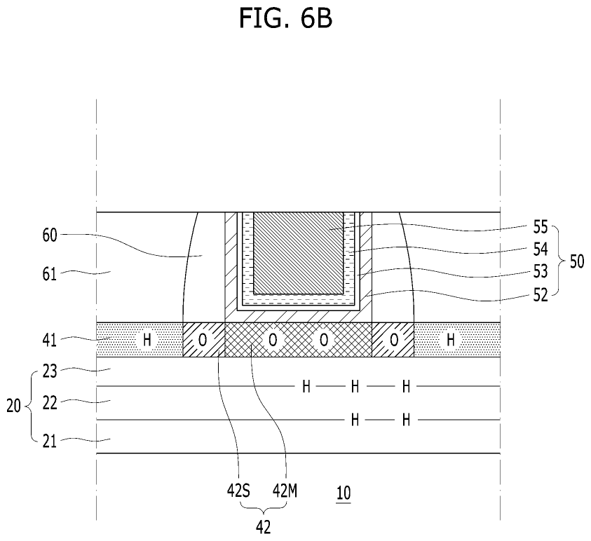

FIGS. 6A and 6B are longitudinal cross-sectional views illustrating methods of manufacturing semiconductor devices according to embodiments of the present disclosure. Referring to FIG. 6A, a method of manufacturing a semiconductor device according to an embodiment of the present disclosure may include performing the processes described with reference to FIGS. 2A to 2K, and performing a gate forming process to form a gate electrode pattern 50. The gate forming process may include forming a gate insulating layer 52, a gate barrier layer 53, and a gate electrode 55 on the main channel layer 42M exposed in the third gate groove G3. Forming the gate barrier layer 53 may include conformally forming at least one of various barrier metals to have a U-shape surrounding side surfaces and a lower surface of the gate electrode 55. Thereafter, the method may further include performing the processes described with reference to FIG. 2M and forming the conductive pattern 73 on the contact pattern 70 with further reference to FIG. 1F.

Referring to FIG. 6B, a method of forming a semiconductor device according to an embodiment of the present disclosure may include performing the processes described with reference to FIGS. 2A to 2K, and performing a gate forming process to form a gate electrode pattern 50. The gate forming process may include forming a gate insulating layer 52, a gate barrier layer 53, a work function adjustment layer 54, and a gate electrode 55 on the main channel layer 42M exposed in the third gate groove G3. Forming the work function adjustment layer 54 may include conformally forming at least one of various work function adjusting metals to have a U-shape surrounding side surfaces and a lower surface of the gate electrode 55. Thereafter, the method may further include performing the processes described with reference to FIG. 2L and forming the conductive pattern 73 on the contact pattern 70 with further reference to FIG. 1G. The semiconductor devices 100F and 100G illustrated in FIGS. 1F and 1G may be manufactured by the above described processes.

According to the embodiments of the present disclosure, off-current and leakage current of the transistor can be reduced, and data retention of the semiconductor device can be improved.

Although the present disclosure has been specifically described according to the above-described embodiments, it should be noted that the above-described embodiments are provided for the purpose of explanation and are not for the limitation thereof. In addition, it will be appreciated by person having ordinary skill in the art that various embodiments are possible within the scope of the present disclosure.

What is claimed is:

1. A semiconductor device comprising:
a substrate;
a buried insulating layer on the substrate;
a channel layer and a source/drain layer on the buried insulating layer; and
a gate electrode pattern on the channel layer,
wherein:
the channel layer and the source/drain layer include an oxide semiconducting material, and
an oxygen vacancy concentration in the source/drain layer is higher than an oxygen vacancy concentration in the channel layer.

2. The semiconductor device of claim 1,
wherein the buried insulating layer includes:
a lower buried insulating layer including silicon oxide;
a middle buried insulating layer including silicon carbon nitride; and
an upper buried insulating layer including silicon nitride.

3. The semiconductor device of claim 1,
wherein a hydrogen concentration in the source/drain layer is higher than a hydrogen concentration in the channel layer.

4. The semiconductor device of claim 1, further comprising:
a gate spacer on a side surface of the gate electrode pattern,
wherein the channel layer further includes:
a main channel layer vertically overlapping the gate electrode pattern; and
a side channel layer vertically overlapping the gate spacer, and
wherein an oxygen concentration in the main channel layer is higher than an oxygen concentration in the side channel layer.

5. The semiconductor device of claim 4,
wherein a hydrogen concentration in the main channel layer is higher than a hydrogen concentration in the side channel layer.

6. The semiconductor device of claim 1, wherein:
the channel layer includes a lower channel layer and an upper channel layer,
the lower channel layer vertically overlaps the upper channel layer, and
an oxygen concentration in the lower channel layer is higher than an oxygen concentration in the upper channel layer.

7. The semiconductor device of claim 1,
wherein the gate electrode pattern includes:
an interface insulating layer on the channel layer;
a gate insulating layer on the interface insulating layer;
a gate barrier layer on the gate insulating layer; and
a gate electrode on the gate barrier layer.

8. The semiconductor device of claim 7,
wherein the gate electrode pattern further includes a work function adjusting layer between the gate barrier layer and the gate electrode.

9. A semiconductor device comprising:
a buried insulating layer on a substrate;
a channel layer and a source/drain layer on the buried insulating layer; and
a gate electrode pattern on the channel layer,
wherein the channel layer and the source/drain layer include an oxide semiconducting material, and
wherein a hydrogen concentration in the source/drain layer is higher than a hydrogen concentration in the channel layer.

10. The semiconductor device of claim 9,
wherein an oxygen concentration in the channel layer is higher than an oxygen concentration in the source/drain layer.

11. A semiconductor device comprising:
a buried insulating layer on a substrate;
a channel layer and a source/drain layer on the buried insulating layer; and
a gate electrode pattern on the channel layer,
wherein the channel layer and the source/drain layer include an oxide semiconducting material, and
wherein an oxygen concentration in the channel layer is higher than an oxygen concentration in the source/drain layer.

12. A method of manufacturing a semiconductor device comprising:
forming a buried insulating layer on a substrate;
forming a first oxide semiconducting layer on the buried insulating layer;
forming a sacrificial gate pattern on the first oxide semiconducting layer;
forming gate spacers on both sides of the sacrificial gate pattern;
forming a gate groove by removing the sacrificial gate pattern between the gate spacers;
exposing sides of the buried insulating layer and the first oxide semiconducting layer by removing a portion of the first oxide semiconducting layer exposed in the gate groove;
forming a source/drain layer by implanting hydrogen ions into the first oxide semiconducting layer;
forming a second oxide semiconducting layer on the buried insulating layer exposed in the gate groove;
forming a channel layer by implanting oxygen ions into the second oxide semiconducting layer; and
forming a gate electrode pattern in the gate groove.

13. The method of claim 12,
wherein forming the buried insulating layer includes:
forming a lower buried insulating layer on the substrate;
forming a middle buried insulating layer on the lower buried insulating layer; and
forming an upper buried insulating layer on the middle buried insulating layer,
wherein:
the lower buried insulating layer includes SiO₂,
the middle buried insulating layer includes SiCO, and
the upper buried insulating layer includes SiN.

14. The method of claim 12,
wherein forming the sacrificial gate pattern includes:
forming a sacrificial insulating layer on the first oxide semiconducting layer;
forming a sacrificial gate electrode layer on the sacrificial insulating layer;
forming a mask pattern on the sacrificial gate electrode layer; and
patterning the sacrificial gate electrode layer and the sacrificial insulating layer by performing an etching process using the mask pattern as an etch mask, and
wherein:
the sacrificial insulating layer includes SiO₂,
the sacrificial gate electrode includes silicon, and
the mask pattern includes SiN.

15. The method of claim 12,
wherein forming the channel layer includes forming a side channel layer by diffusing the oxygen ions into a portion of the source/drain layer.

16. The method of claim 12,
wherein forming the channel layer includes
forming a lower channel layer having a first oxygen concentration and an upper channel layer having a second oxygen concentration, and
wherein the first oxygen concentration is higher than the second oxygen concentration.

17. The method of claim 12,
wherein the first oxide semiconducting layer and the second oxide semiconducting layer include a same material.

18. The method of claim 12,
wherein implanting the hydrogen ions includes performing at least one of a hydrogen plasma process or an annealing process in a hydrogen atmosphere.

19. The method of claim 12,
wherein implanting the oxygen ions include performing at least one of an oxygen plasma process or an annealing process in an oxygen atmosphere.

20. A method of manufacturing a semiconductor device, the method comprising:
forming a buried insulating layer on a substrate;
forming a first oxide semiconducting layer on the buried insulating layer;
forming an interlayer insulating layer on the first oxide semiconducting layer;
forming a groove passing through the interlayer insulating layer and the first oxide semiconducting layer to expose a top surface of the buried insulating layer;
forming a second oxide semiconducting layer in the groove;
forming a gate electrode pattern in the groove; and
implanting oxygen ions into the second oxide semiconducting layer.
